(19) United States
(12) Patent Application Publication
(10) Pub. No.: US 2011/0056555 A1
(43) Pub. Date: Mar. 10, 2011

(54) Photovoltaic Modules Containing Plasticized Intermediate Layer Films With High Volume Resistivity and Good Penetration Resistance

(75) Inventor: Uwe Keller, Bonn (DE)

(73) Assignee: KURARAY EUROPE GMBH, Frankfurt am Main (DE)

(21) Appl. No.: 12/991,573

(22) PCT Filed: May 8, 2009
(86) PCT No.: PCT/EP09/55586

§ 371 Date: Nov. 8, 2010

(30) Foreign Application Priority Data
May 8, 2008 (DE) 10 2008 001 654.3

(51) Int. Cl. H01L 31/02; H01L 31/18

(52) U.S. Cl. 136/256

(57) ABSTRACT

Plasticizer-containing films based on polyvinyl acetal and comprising more than 10 ppm of metal ions selected from the group of alkaline earth metals, zinc and aluminum and less than as 150 ppm of alkali metal ions are used for the production of photovoltaic modules. The films preferably exhibit an electrical volume resistivity of more than 1E11 ohm·cm in an ambient of 85% RH/23° C. The photovoltaic modules may be used as facade elements, roof surfaces, winter garden coverings, sound-insulating walls, balcony or balustrade elements, or as components of window surfaces.

### TECHNICAL FIELD

The invention relates to the production of photovoltaic modules using plasticizer-containing films based on polyvinyl acetal having increased volume resistivity and good penetration resistance.

### PRIOR ART

Photovoltaic modules consist of a photosensitive semiconductor layer that is provided with a transparent covering as a protection against external effects. As photosensitive semiconductor layer, monocrystalline solar cells or supported polycrystalline, thin semiconductor layers can be used. Thin-film solar modules consist of a photosensitive semiconductor layer applied to a substrate, such as a transparent sheet or a flexible support film, by means of for example evaporation coating, chemical vapour deposition, sputtering, or wet deposition.

Both systems are often laminated between a glass panel and a rigid, back covering panel made for example of glass or plastics by means of a transparent adhesive.

The transparent adhesive must completely enclose the photosensitive semiconductor layer and its electrical interconnections, must be UV stable and moisture insensitive, and must be completely bubble-free after the lamination process.

As transparent adhesive, thermosetting casting resins or crosslinkable, ethylene vinyl acetate-(EVA)-based systems are often used, as disclosed for example in DE 41 22 721 C1 or DE 41 28 766 A1. In the uncured state, these adhesive systems can be adjusted to such a low viscosity that they enclose the solar cell units in a bubble-free manner. After addition of a curing or crosslinking agent, a mechanically robust adhesive layer is obtained. A disadvantage of these adhesive systems is that during the curing process, aggressive substances, such as acids, which may destroy the photosensitive semiconductor layers, in particular thin-film modules, are often released. In addition, some casting resins tend to form bubbles or delaminate after a few years as a result of UV radiation.

An alternative to thermosetting adhesive systems is the use of plasticizer-containing films based on polyvinyl acetals, such as polyvinyl butyral (PVB) known from the manufacturing of laminated glass. The solar cell units are covered with one or more PVB films, and the films are bonded with the desired covering materials to form a laminate under elevated pressure and temperature.

Methods for the production of solar modules using PVB films are known for example from DE 40 26 165 C2, DE 42 278 60 A1, DE 29 237 70 C2, DE 35 38 986 C2, or U.S. Pat. No. 4,321,418. The use of PVB films in solar modules as laminated safety glass is disclosed for example in DE 20 302 045 U1, EP 1617487 A1, and DE 35 389 86 C2. These documents, however, do not contain any information about the mechanical, chemical, and electrical properties of the PVB films used.

The electrical properties of the films in particular have become more and more important with increasing efficiency of the photosensitive semiconductor layers and global distribution of solar modules. Loss of charge or even short circuits of the semiconductor layer must also be avoided under extreme weather conditions, such as tropical temperatures, high humidity, or strong UV radiation, over the entire lifetime of the module. In accordance with CEI 61215, photovoltaic modules are subjected to numerous tests (damp heat test, wet leakage current test) in order to reduce leakage currents of the modules.

It is known that the electrical resistance of PVB films declines sharply with increasing moisture content, which strongly favours the occurrence of leakage currents in photovoltaic modules. In the edge region of the photovoltaic module, the films, as encapsulation material, are exposed and subjected to ambient conditions, such as high ambient humidity. Here, the water content of the films in the edge region can strongly increase and take on values up to the equilibrium moisture content (approx. 3% by weight). The increased water content in the edge region of the film strongly reduces the electrical resistance thereof in this region. The water content does decrease again towards the middle of the film, but in order to avoid leakage currents, the photosensitive semiconductor layers can therefore not be placed all the way into the edge region of the film or module. This reduces the surface density and consequently the current efficiency of the module.

Solar cells, in particular photosensitive semiconductor layers of thin-film solar modules, for example based on CIS (copper/indium/(di)selenide) or copper/indium/gallium/sulphide/selenide (CIGS), or the thin layers (TCO: transparent conductive oxide) used as electric conductors are susceptible to chemical corrosion. The encapsulation material must therefore be as chemically inert as possible and should contain no aggressive chemical additives, such as curing agents, crosslinkers or primers. The presence of water, alkali metal ions or acid traces should also be avoided.

The plastics normally used in photovoltaic modules are generally known as effective electrically insulating materials, but do exhibit residual conductivities that can generally be attributed to impurities, such as water, ionic catalyst residues or salts. In particular, the interaction between ionic impurities and diffused water (which should always be expected in practice with the ambient humidity that is typical during use) accounts for a substantial portion of the residual conductivity.

For this reason it seems obvious to produce adhesive films for photovoltaic modules with a minimum salt content. In the case of conventional polyvinyl butyral (PVB) films, which are often used to produce laminate glass, the salt content of the film depends, on the one hand, on the salt content of the PVB polymer, which typically contains salts of mineral acids, such as NaCl, KCl, NaNO₃, KNO₃, Na₂SO₄ or K₂SO₄ in amounts between 20-300 ppm following the production method depending on the quality of the washing process employed. On the other hand, alkaline salts and alkaline earth metal salts are often added to conventional PVB films as so-called non-stick agents in order to increase the penetration resistance of the glass/film/glass compounds in amounts of approximately 20-500 ppm. These salts are required in order to set a sufficiently low adhesion level of the film to the glass. If a photovoltaic module produced using PVB film also exhibits the safety properties of a laminate glass in addition to a high level of power generation, for example because the module is part of a glass facade, there is the problem that the combinations and amounts of the non-stick agents normally used to reduce adhesion may also reduce electrical resistance and increase corrosion of the semiconductor layers.

The safety properties of a glass component part of laminate glass are therefore generally deemed to be sufficient if the component part satisfies at least class 3B during impact testing in accordance with EN 12600, in which a 50 kg double-tyre impactor is swung against the glass from a drop height of 190 mm. If the impactor does not shatter the glass component or no excessively large openings are formed and no sharp-edged fragments come loose, the test is deemed to have been passed. In the case of the adhesion-reduced PVB films used conventionally and measuring 0.76 mm in thickness, laminate glasses pass the impact test, even with substantially greater drop heights, in particular 1200 mm, thus reaching the highest resistance class 1B. If a photovoltaic module is integrated into a building facade, for example as a glass component, and the conventional high demands placed on the shatterproof quality of a laminate glass are satisfied, the PVB film should exhibit moderate adhesion to the glass or adjacent functional layers.

### TECHNICAL OBJECT

The object of the present invention was therefore to provide plasticizer-containing films based on polyvinyl acetal having high volume resistivity and good penetration resistance in conjunction with glass panels for the production of photovoltaic modules.

### TECHNICAL SOLUTION

It was found that a PVB film with an addition of, for example, alkaline earth salts and also having a low content of alkali metal salts makes it possible to obtain photovoltaic modules having sufficient penetration properties. Furthermore, the volume resistivity of the plasticizer-containing films based on polyvinyl acetals is increased further and the corrosivity of the semiconductor layers of these films can also be reduced.

### ILLUSTRATION OF THE INVENTION

The present invention therefore relates to photovoltaic modules comprising a laminate of

a) a transparent front covering
b) one or more photosensitive semiconductor layers
c) at least one plasticizer-containing film based on polyvinyl acetal, and
d) a back covering,
the plasticizer-containing film based on polyvinyl acetal c) comprising more than 10 ppm metal ions selected from the group of alkaline earth metals, zinc and aluminium, and less than 150 ppm alkali metal ions.

When using a plurality of different metal ions, the mentioned concentrations are based on the respective sums of the individual concentrations, i.e. on the total concentration of alkali metal ions or multivalent metal ions.

The film c) used in accordance with the invention preferably contains more than 15 ppm, preferably more than 20 ppm, preferably more than 30 ppm, preferably more than 50 ppm, preferably more than 75 ppm, preferably more than 100 ppm, preferably more than 125 ppm and particularly preferably more than 150 ppm of alkaline earth metal (Be, Mg, Ca, Sr, Ba, Ra), zinc or aluminium ions. On the other hand however, no more than 1000 ppm of the mentioned multivalent metals should be contained in order to avoid undesired cloudiness of the films.

At the same time, the content of alkali metal ions (Li, Na, K, Rb, Cs, Fr) in the plasticizer-containing film based on polyvinyl acetal should be set to be as low as possible. In particular, the film contains less than 100 ppm, preferably less than 75 ppm, preferably less than 50 ppm, preferably less than 25 ppm, preferably less than 15 ppm, preferably less than 10 ppm and particularly preferably less than 5 ppm of alkali metal ions.

The respective alkaline earth metal, zinc, aluminium or alkali metal ions are added to the film mixture in the form of salts of monovalent or multivalent inorganic acids or salts of monovalent or multivalent organic acids. Examples of counterions include, for example, salts of organic carboxylic acids, such as formates, acetates, trifluoroacetates, propionates, butyrates, benzoates, 2-ethylhexanoates, etc., preferred carboxylic acids having less than 10 C atoms, preferably less than 8, preferably less than 6, preferably less than 4 and particularly preferably having less than 3 C atoms being used. Examples of inorganic counterions include chlorides, nitrates, sulphates and phosphates.

The films used according to the invention preferably exhibit, at an ambient humidity of 85% RH at 23° C., a resistivity of at least 1E+11 ohm*cm, preferably at least 5E+11 ohm*cm, 1E+12 ohm*cm, 5E+12 ohm*cm, 1E+13, 5E+13 ohm*cm, or 1E+14 ohm*cm.

In order to produce polyvinyl acetal, polyvinyl alcohol is dissolved in water and acetalised with an aldehyde, such as butyraldehyde with the addition of an acid catalyst. The polyvinyl acetal produced is separated, washed neutral, optionally suspended in an alkali aqueous medium, and then washed neutral again and dried.

The acid used for acetalisation must be neutralised again once the reaction has ended. Inter alia, a low content of alkali metal ions may be achieved with synthesis of the polyvinyl acetal by dispensing with the sodium or potassium hydroxides or carbonates normally used to neutralise the catalyst, or by thoroughly washing the polyvinyl acetal obtained during acetalisation. As an alternative to the bases of NaOH or KOH, the catalyst acid from the acetalisation step may be neutralised, for example by injecting carbon dioxide or ethylene oxide.

The polyvinyl alcohol content of the polyvinyl acetal may be adjusted by the amount of the aldehyde used during acetalisation.

It is also possible to perform the acetalisation using other or additional aldehydes having 2-10 carbon atoms (for example valeraldehyde).

The films based on plasticizer-containing polyvinyl acetal preferably contain uncrosslinked polyvinyl butyral (PVB) obtained by acetalising polyvinyl alcohol with butyraldehyde.

The use of crosslinked polyvinyl acetals, in particular crosslinked polyvinyl butyral (PVB), is also possible. Suitable crosslinked polyvinyl acetals are described for example in EP 1527107 B1 and WO 2004/063231 A1 (thermal self-crosslinking of carboxyl group-containing polyvinyl acetals), EP 1606325 A1 (polyvinyl acetals crosslinked with polyaldehydes), and WO 03/020776 A1 (polyvinyl acetals crosslinked with glyoxylic acid). The disclosure of these patent applications is fully incorporated herein by reference.

Terpolymers of hydrolysed vinyl acetate/ethylene copolymers can also be used as polyvinyl alcohol within the scope of the present invention. These compounds are normally hydrolysed to more than 98 mol % and contain 1 to 10% by weight of ethylene-based units (for example type “Exceval” from Kuraray Europe GmbH).

Copolymers hydrolysed from vinyl acetate and at least a further ethylenically unsaturated monomer may also be used as polyvinyl alcohol within the scope of the present invention.

Within the scope of the present invention the polyvinyl alcohols may be used in pure form or as a mixture of polyvinyl alcohols with different degrees of polymerization or hydrolysation.

Polyvinyl acetals contain in addition to the acetal units also units resulting from vinyl acetate and vinyl alcohol. The polyvinyl alcohol content of the polyvinyl acetals used in accordance with the invention is preferably less than 22% by weight, 20% by weight or 18% by weight, less than 16% by weight or 15% by weight, and in particular less than 14% by weight. The polyvinyl alcohol content should not fall below 12% by weight.

The polyvinyl acetate content of the polyvinyl acetal used in accordance with the invention is preferably below 5% by weight, below 3% by weight or below 1% by weight, particularly preferably below 0.75% by weight, more particularly preferably below 0.5% by weight and in particular below 0.25% by weight.

The degree of acetalisation can be calculated from the polyvinyl alcohol content and from the residual acetate content.

The films preferably have a plasticizer content of a maximum of 40% by weight, 35% by weight, 32% by weight, 30% by weight, 28% by weight, 26% by weight, 24% by weight, 22% by weight, 20% by weight, 18% by weight, 16% by weight, whereby for reasons of the processability of the film, the plasticizer content should not fall below 15% by weight (in each case based on the total film formulation). Films or photovoltaic modules according to the invention can contain one or more plasticizers.

Suitable plasticizers for the films used in accordance with the invention are one or more compounds selected from the following groups:

esters of multivalent aliphatic or aromatic acids, for example dialkyl adipates such as dihexyl adipate, dioctyl adipate, hexylcyclohexyl adipate, mixtures of heptyl and nonyl adipates, diisononyl adipate, heptylnonyl adipate and esters of adipic acid with cycloaliphatic or ether compound-containing ester alcohols, dialkyl sebacates such as dibutyl sebacate and esters of sebacic acid with cycloaliphatic or ether compound-containing ester alcohols, esters of phthalic acid such as butylbenzyl phthalate or bis-2-butoxyethyl phthalate,

esters or ethers of multivalent aliphatic or aromatic alcohols or oligoether glycols having one or more unbranched or branched aliphatic or aromatic substituents, such as esters of di-, tri- or tetraglycols having linear or branched aliphatic or cycloaliphatic carboxylic acids; Examples of the latter group may include diethylene glycol-bis-(2-ethyl-hexanoate), triethylene glycol-bis-(2-ethyl-hexanoate), triethylene-glycol-bis-(2-ethylbutanoate), tetraethylene glycol-bis-n-heptanoate, triethylene glycol-bis-n-heptanoate, triethylene glycol-bis-n-hexanoate, tetraethylene glycol-dimethyl ether and/or dipropylene glycol benzoate.

Phosphates having aliphatic or aromatic ester alcohols, such as tris(2-ethylhexyl)phosphate (TOF), triethyl phosphate, diphenyl-2-ethylhexyl phosphate, and/or tricresyl phosphate.

Esters of citric acid, succinic acid and/or fumaric acid.

Compounds that are particularly suitable for use as plasticizers for the films used in accordance with the invention include one or more of those selected from the following group: di-2-ethylhexyl sebacate (DOS), di-2-ethylhexyl adipate (DOA), dihexyl adipate (DHA), dibutyl sebacate (DBS), triethylene glycol-bis-n-heptanoate (3G7), tetraethylene glycol-bis-n-heptanoate (4G7), triethylene glycol-bis-2-ethyl hexanoate (3G0 or 3G8), tetraethylene glycol-bis-n-2-ethyl hexanoate (4G0 or 4G8), di-2-butoxyethyl-adipate (DBEA), di-2-butoxyethoxyethyl-adipate (DBEEA), di-2-butoxyethyl sebacate (DBES), di-2-ethylhexyl phthalate (DOP), di-isononyl phthalate (DINP), triethylene glycol-bis-isononanoate, triethylene glycol-bis-2-propyl hexanoate, tris(2-ethylhexyl)phosphate (TOF), 1,2-cyclohexane dicarboxylic acid diisononyl ester (DINCH) and dipropylene glycol benzoate.

Particularly suitable as plasticizers for the films used in accordance with the invention are plasticizers, the polarity of which, expressed by the formula 100×0/(C+H), is less than/equal to 9.4; 0, C, and H representing the number of oxygen, carbon, and hydrogen atoms in the respective molecule. The following table shows plasticizers applicable according to the invention and polarity values thereof in accordance with the formula 100×0/(C+H).

TABLE 1

| Name | Polarity Value |
|---|---|
| di-2-ethylhexyl sebacate (DOS) | 5.3 |
| diisononylcyclohexane dicarboxylic | 5.4 |
| acid ester (DINCH) | |
| di-2-ethylhexyl adipate (DOA) | 6.3 |
| di-2-ethylhexyl phthalate (DOP) | 6.5 |
| Dihexyl adipate (DHA) | 7.7 |
| Dibutyl sebacate (DBS) | 7.7 |
| triethylene glycol-bis-2-propyl | 8.6 |
| hexanoate | |
| triethylene glycol-bis-i-nonanoate | 8.6 |
| di-2-butoxyethyl sebacate (DBES) | 9.4 |
| triethylene glycol-bis-2-ethyl | 9.4 |
| hexanoate (3G8) | |

Furthermore, the ion mobility, which might depend on the water content of the film, and hence the resistivity can be affected by the addition of silicic acid, in particular pyrogenic SiO₂. The plasticizer-containing films based on polyvinyl acetal preferably contain 0.001 to 15% by weight, preferably 0.01 to 10% by weight and in particular 2 to 5% by weight of SiO₂.

Furthermore, the films according to the invention may also additionally contain conventional additives, such as oxidation stabilizers, UV stabilizers, colourants, pigments and non-stick agents.

The production and composition of films based on polyvinyl acetals is described in principle for example in EP 185 863 B1, EP 1 118 258 B1, WO 02/102591 A1, EP 1 118 258 B1, or EP 387 148 B1.

Photovoltaic modules are produced by laminating the transparent front covering a), the photosensitive semiconductor layers b) and the back covering d) using at least one plasticizer-containing film based on polyvinyl acetal c) by fusing the films in such a way that bubble-free and waviness-free encapsulation of the photosensitive semiconductor layer is obtained.

In this variant of the photovoltaic modules according to the invention, the photosensitive semiconductor layers are embedded between two films c) and bonded to the coverings a) and d) in this manner.

The thickness of the films based on plasticizer-containing polyvinyl acetal is usually 0.38, 0.51, 0.76, 1.14, 1.52, or 2.28 mm.

In particular in the case of thin-film solar modules, the photosensitive semiconductor layer is directly applied to a support (for example by evaporation coating, chemical vapour deposition, sputtering, or wet deposition). An encapsulation of the photosensitive semiconductor layer is not possible here.

In one variant of the photovoltaic modules according to the invention, the photosensitive semiconductor layers are applied to the covering d) (for example by evaporation coating, chemical vapour deposition, sputtering, or wet deposition) and bonded to the transparent front covering a) by means of at least one film c).

In another variant, the photosensitive semiconductor layers are applied to the transparent front covering a) and bonded to the back covering d) by means of at least one film c).

In thin-film modules the entire surface of the photosensitive semiconductor layer is generally applied to the support, i.e. up to the edge of the support. Some of the photosensitive semiconductor layer is then removed again at the edge in such a way that, for insulation purposes, a semi-conductor-free region remains (so-called edge coating removal). As a result of high resistance values of the film used in accordance with the invention, this edge region may be produced so as to be very narrow, preferably less than 3 cm, particularly preferably less than 2 cm and in particular less than 1 cm narrow.

During the lamination process, films used according to the invention fill the voids existing at the photosensitive semiconductor layers or the electrical connections thereof.

The transparent front covering normally consists of glass or PMMA. The back covering of the photovoltaic module according to the invention can consist of glass, plastic, or metal or composites thereof, at least one of the supports possibly being transparent. It is also possible to design one or both of the coverings as laminated glass (i.e. as laminate made of at least two glass panels and at least one PVB film) or as insulation glass with a gas interspace. Naturally, combination of these measures is also possible.

The photosensitive semiconductor layers used in the modules do not need to have any special properties. Monocrystalline, polycrystalline, or amorphous systems can be used.

For lamination of the composite thus obtained, the methods known to those skilled in the art can be used with or without prior making of a pre-laminate.

So-called autoclave processes are performed at an elevated pressure of approximately 10 to 15 bar and temperatures of 130 to 145° C. over the course of approximately 2 hours. Vacuum bag or vacuum ring methods, for example according to EP 1 235 683 B1, operate at approximately 200 mbar and 130 to 145° C.

Vacuum laminators are preferably used for the production of the photovoltaic modules according to the invention. They consist of a heatable and evacuateable chamber, wherein laminated glasses may be laminated within 30-60 minutes. Reduced pressures of 0.01 to 300 mbar and temperatures of 100 to 200° C., in particular 130-160° C., have proven to be of value in practice.

Alternatively, a composite assembled as described above can be pressed into a module according to the invention between at least one pair of rollers at a temperature of 60 to 150° C. Installations of this kind are known for the production of laminated glasses and usually have at least one heating tunnel upstream or downstream from the first pressing apparatus in installations having two pressing apparatuses.

### INDUSTRIAL APPLICATION

The invention further relates to the use of plasticizer-containing films based on polyvinyl acetal c), containing more than 10 ppm of metal ions selected from the group of alkaline earth metals, zinc and aluminium and less than 150 ppm of alkali metal ions, or being constructed in accordance with the preferred embodiments mentioned, for the production of photovoltaic modules.

Photovoltaic modules according to the invention can be used as facade elements, roof surfaces, winter garden coverings, sound-insulating walls, balcony or balustrade elements, or as components of window surfaces.

### Measuring Procedures:

The measurement of the volume resistivity of the film is performed in accordance with DIN IEC 60093 at a defined temperature and ambient humidity (23° C. and 85% RH) after the film has been conditioned for at least 24 h under these conditions. For the execution of the measurement, a plate electrode of type 302 132 from the company Fetronic GmbH and an instrument for resistivity measurement ISO-Digi 5 kV from the company Amprobe was used. The testing voltage was 2.5 kV, the wait time after application of the testing voltage until acquisition of measured data was 60 sec. In order to guarantee sufficient contact between the flat plates of the measuring electrode and the film, the surface roughness Rz of the film should not be greater than 10 mm when measuring in accordance with DIN EN ISO 4287; i.e. the original surface of the PVB film has to be smoothed by thermal reembossing prior to the resistivity measurement, if necessary.

The polyvinyl alcohol and polyvinyl alcohol acetate contents of the polyvinyl acetals were determined in accordance with ASTM D 1396-92. Analysis of the metal ion content took place by means of atomic absorption spectroscopy (AAS). The water or moisture content of the films is determined by the Karl Fischer method.

The impact test is carried out in accordance with EN 12600; the results are given in accordance with the classification of this standard.

The adhesiveness of the film to glass is given by ‘pummel values’, in each case based on the fire or tin side of the glass. The pummel test is carried out in a manner known to the person skilled in the art.

The cloudiness is determined by the haze value in % in accordance with ASTM 1003 D on a smooth film.

In order to assess the adhesiveness of a PVB film, the compression shear test is carried out on a glass/glass laminate having no solar cells in the manner disclosed in DE 197 56 274 A1. In order to produce the test specimen the PVB film to be tested is arranged between two flat silicate glass panels measuring 300 mm×300 mm and having a thickness of 2 mm, the air is evacuated in a pre-laminate oven with calendar rollers to form a glass pre-laminate and this is then pressed into a flat laminated safety glass in an autoclave at a pressure of 12 bar and at a temperature of 140° C. within a total time of 90 mins. 10 samples measuring 25.4 mm×25.4 mm are cut from the laminated safety glass thus produced. These are clamped in a testing apparatus at an angle of 45° in accordance with DE 197 56 274 A1, the depth of the clearances being approximately two thirds of the respective glass thickness. The upper half is loaded with a continuously rising, precisely vertical force directed downwards until shearing of the test specimen, i.e. the laminated safety panels to be tested is observed.

The test parameters are as follows:

TABLE 2

| Test specimen | Square, 25.4 mm × 25.4 mm |
|---|---|
| laying | Lower panel with the air |
| | or fire side facing the |
| | film in each case |
| | (air/air) or the tin side |
| | of the upper and lower |
| | panels facing the film in |
| | each case (bath/bath) |
| Storage before testing | 4 h at a normal climate |
| | 23° C./50% RH |
| Feed | 2.5 mm/min |
| Number of samples | 10 |
| Evaluation | Maximum force required to |
| | shear the film from the |
| | glass. The force is based |
| | on the sample surface (in |
| | N/mm² or psi) |

For each test specimen the force exerted during shearing is averaged linearly from ten identical test specimens. Reference is made in the following examples and claims to the average compression shear test value, this average value being ascertained from 10 measurements. For the rest, reference should be made to DE 197 56 274 A1.

### EXAMPLES

Films 0.76 mm thick were produced using the mixtures of the composition shown in the following tables and their electrical resistance and adhesion to glass as well as the impact resistance of laminate glasses formed by 5 mm float glass/film/5 mm float glass were tested.

The amounts detailed in tables 3 and 4 are given in % by weight, based on the sum of PVB and plasticizer. 3G8 is triethylene glycol-bis-2-ethyl hexanoate, AEROSIL 130 and TINUVIN 328 are commercial products from Evonik Degussa GmbH or CIBA. The volume resistivity is given in ohms in accordance with DIN CEI 60093 for a film climatised at 23° C./85% RH (as described above).

A highly viscous polyvinyl butyral having a viscosity of 60-90 mPas (measured in accordance with DIN 53015 as 5% solution in ethanol (with 5% water) at 20° C.) was used as PVB having a PVA content of 20.0% by weight, its content of Na ions being less than 3 ppm as a result of thorough washing.

It can be seen that films having the salt concentration in accordance with the invention exhibit high resistivity with good penetration resistance of the glass/film/glass laminates produced hereby. Films of this type are suitable for photovoltaic applications. A further improvement of the resistivity could be achieved by adding SiO₂.

TABLE 3

| | Example: | | |
|---|---|---|---|
| | VB1 | B1 | B2 |
| | Brief description | | |
| | | With 250 | With 500 |
| | No metal | ppm | ppm |
| | ions | MgAc₂ | MgAc₂ |
| PVB | 76 | 76 | 76 |
| 3G8 | 24 | 24 | 24 |
| AEROSIL 130 | — | — | — |
| TINUVIN 328 | 0.15 | 0.15 | 0.15 |
| *sodium acetate | 0 | 0.025 | 0 |
| MgAc2*4H₂O | — | 0.025 | 0.05 |
| Magnesium content in ppm | — | 28 | 56 |
| Sodium content in ppm | <2 | <2 | <2 |
| Test results as | | | |
| laminated safety glass | | | |
| Water content end | 0.43 | 0.43 | 0.43 |
| laminate | | | |
| Pummel value f-side | 9 | 6 | 2.5 |
| Pummel value s-side | 8.5 | 5.5 | 2 |
| Shear test | 37.9 | 24.0 | 15.7 |
| Cloudiness haze | 0.02 | 0.03 | 0.05 |
| Impact test | 2B | 1B | 1B |
| Test results on the film | | | |
| Volume resistivity | 4.88E+11 | 5.50E+11 | 7.20E+11 |

TABLE 4

Example:

| | |
|---|---|
| VB2 | B3 |

Brief description

| | With 1% | |
|---|---|---|
| | SiO₂, no | With 1% |
| | metal ions | SiO₂ |
| PVB | 76 | 76 |
| 3G8 | 24 | 24 |
| AEROSIL 130 | 1 | 1 |
| TINUVIN 328 | 0.15 | 0.15 |
| MgAc2*4H₂O | — | 0.30 |
| Magnesium content in ppm | — | 336 |
| Sodium content in ppm | <2 | <2 |
| Test results as laminated | | |
| safety glass | | |
| Water content end | 0.43 | 0.43 |
| laminate | | |
| Pummel value f-side | 10 | 7.5 |
| Pummel value s-side | 10 | 7 |
| Shear test | 48.2 | 29.7 |
| Cloudiness haze | 0.54 | 0.35 |
| Impact test | 3B | 1B |
| Test results on the film | | |
| Volume resistivity | 5.70E+11 | 1.50E+12 |

1-10. (canceled)

11. A photovoltaic module comprising a laminate of
a) a transparent front covering
b) one or more photosensitive semiconductor layers
c) at least one plasticizer-containing film based on polyvinyl acetal, and
d) a back covering,
wherein the plasticizer-containing film based on polyvinyl acetal c) comprises more than 10 ppm of metal ions selected from the group of alkaline earth metals, zinc and aluminium and less than 150 ppm of alkali metal ions.

12. The photovoltaic module of claim 11, wherein the plasticizer-containing films based on polyvinyl acetal c) have a plasticizer content of a maximum of 40% by weight.

13. The photovoltaic module of claim 11, wherein the plasticizer-containing films based on polyvinyl acetal c) have an electrical volume resistivity of more than 1E11 ohm·cm in an ambient climate of 85% RH/23° C.

14. The photovoltaic module of claim 11, wherein the polyvinyl acetal has a polyvinyl acetate content of less than 5% by weight.

15. The photovoltaic module of claim 11, wherein one or more compounds, the polarity of which, expressed by the formula 100×O/(C+H), is less than/equal to 9.4, 0, C, and H representing the number of oxygen, carbon, and hydrogen atoms in the respective molecule, are used as plasticizers.

16. The photovoltaic module of claim 11, wherein the polyvinyl acetal has a polyvinyl alcohol content of less than 22% by weight.

17. The photovoltaic module of claim 11, wherein the plasticizer-containing film based on polyvinyl acetal c) contains 0.001 to 15% by weight of SiO₂.

18. The photovoltaic module of claim 11, wherein one or more photosensitive semiconductor layers b) are applied to a transparent front covering a) or a back covering d) and are bonded together by at least one plasticizer-containing film based on polyvinyl acetal c).

19. In a process for the production of photovoltaic modules where a polyvinyl acetal film is employed, the improvement comprising employing, as at least one film, a plasticizer-containing film of claim 11.

20. A photovoltaic module of claim 11 which is a facade element, roof surface, winter garden covering, sound-insulating wall, balcony or balustrade element, or a component of a window surface.
